(19) United States
(12) Patent Application Publication
(10) Pub. No.: US 2011/0241735 A1
(43) Pub. Date: Oct. 6, 2011

(54) DRIVING CIRCUIT AND DRIVING METHOD FOR CURRENT-DRIVEN DEVICE

(75) Inventor: Chia-Ling CHOU, Hsin-Chu (TW)

(73) Assignee: AU OPTRONICS CORP., Hsinchu (TW)

(21) Appl. No.: 12/940,550

(22) Filed: Nov. 5, 2010

(30) Foreign Application Priority Data
Apr. 2, 2010 (TW) 099110409

(51) Int. Cl. H03K 3/00

(52) U.S. Cl. 327/108

(57) ABSTRACT

A driving circuit and a driving method for drive a current-driven device having a first terminal and a second terminal are provided. The first terminal is coupled to a first power source potential. The driving circuit includes a switching module, a first capacitor and a second capacitor. The switch module is coupled to a data line, the second terminal and a second voltage source and further is for determining whether to allow a current to flow through the current-driven device. A first end and a second end of the first capacitor are respectively coupled to different nodes in the switch module. The first end of the first capacitor receives a potential on the data line in a particular time period. A first end and a second end of the second capacitor are respectively coupled to the second end of the first capacitor and a second power source potential.

### BACKGROUND

1. Technical Field

The present invention generally relates to a display technique, more particularly to a driving circuit and a driving method for driving a current-driven device such as a light emitting diode.

2. Description of the Related Art

A conventional organic light emitting diode (hereinafter, referred to as OLED) display device utilizes a plurality of pixel circuits that are arranged in matrices and that can emit light of different brightness to achieve the function of displaying images. And, the conventional pixel circuit utilizes transistors and a capacitor for storing charges to control the brightness performance of the OLED. According to the current driving approach, the final output of data programmed in each the pixel circuit is in the form of current. The OLED is driven by a driving current, and the pixel brightness in the display device depends on the magnitude of driving current passed through the OLED.

FIG. 1 illustrates a circuit diagram of a conventional pixel circuit for an OLED display device. As shown in FIG. 1, the pixel circuit 10 includes a driving circuit 12 and an OLED 16. The driving circuit 12 has a two-transistor, one-capacitor structure (2T1C) for controlling the brightness performance of the OLED 16. Herein, each transistor includes a source, a drain, and a gate. To be specific, the driving circuit 12 includes a N-type transistor M1, a P-type transistor M2, and a capacitor C1. The drain of the N-type transistor M1 is electrically coupled to a data line DL, and the gate of the N-type transistor M1 is electrically coupled to a scan signal SCAN, where the gate of the N-type transistor M1 receives the scan signal SCAN to determine whether transmitting a written data potential from the data line DL to the source of the N-type transistor M1. The gate of the P-type transistor M2 is electrically coupled to the source of the N-type transistor M1, and the source of the P-type transistor M2 is electrically coupled to a power source voltage OVDD, and the drain of the P-type transistor M2 is electrically coupled to an anode of the OLED 16. The cathode of the OLED 16 is electrically coupled to another power source voltage OVSS. Two ends of the capacitor C1 are respectively electrically connected to the gate and the source of the P-type transistor M2.

However, the threshold voltages of the transistors M2 for respective pixel circuits 10 of the OLED display device are not identical due to influence of fabrication process. In spite of the same written data potential is given, the driving currents generated by the respective pixel circuits 10 and passed through OLEDs 16 are not identical, such that the brightness performances of light emitted by the OLEDs 16 are fluctuant among the pixel circuits. The effect of the threshold voltage differences on driving current variations is necessary to be diminished.

### BRIEF SUMMARY

The present invention is directed to provide a driving circuit adapted to drive a current-driven device, in order that the issue of uneven brightness resulting from the effect of the difference among threshold voltages of transistors and applied on driving current variations associated with the prior art is improved.

In accordance with another aspect of the present invention, there is provided a driving method adapted to drive a current-driven device, in order that the issue of uneven brightness resulting from non-identical threshold voltages of transistors associated with the prior art is improved.

In accordance with one embodiment of the present invention, there is provided a driving circuit adapted to drive a current-driven device that has a first terminal and a second terminal, wherein the first terminal of the current-driven device is electrically coupled to a first predetermined potential. The driving circuit includes a plurality of switches, in which there is a control end, a first passage end and a second passage end for each the switch. Specifically, the driving circuit includes a first switch, a second switch, a third switch, a first capacitor and a second capacitor. The control end of the first switch is electrically coupled to a first control signal, and it is determined whether transferring a potential on the data line from the first passage end of the first switch to the second passage end of the first switch based on the first control signal. The control end of the second switch is electrically coupled to the second passage end of the first switch, the first passage end of the second switch is electrically coupled to the second terminal of the current-driven device. The control end of the third switch is electrically coupled to a second control signal, the first passage end of the third switch electrically coupled to the second passage end of the second switch, and the second passage end of the third switch electrically coupled to a second predetermined potential. Two ends of the first capacitor are respectively electrically coupled to the control end and the second passage end of the second switch. Two ends of the second capacitor are respectively connected to the first passage end and the second passage end of the third switch.

In accordance with one embodiment of the present invention, the driving circuit is as mentioned above, wherein a capacitance of said second capacitor is larger than that of the first capacitor.

In accordance with one embodiment of the present invention, the driving circuit is as mentioned above, wherein said first switch, said second switch and said third switch are all N-type transistors.

In accordance with another embodiment of the present invention, the driving circuit is as mentioned above, wherein said first switch and said third switch are both N-type transistors, and said second switch is a P-type transistor.

In accordance with yet another embodiment of the present invention, the driving circuit is as mentioned above, wherein said first switch, said second switch and said third switch are all P-type transistors.

In accordance with another aspect of the present invention, the present invention further provides a driving method applicable to the above-mentioned driving circuit. The driving method includes the following steps of: (1) At a first time point, the first switch, the second switch, and the third switch are all “ON” state, and thereby a precharged potential on the data line is initially transferred/delivered to the first end of the first capacitor; (2) At a second time point, the first switch and the second switch are both still “ON” state and the third switch is “OFF” state, and the second predetermined potential is initially terminated to be introduced into the interior of the driving circuit; then, the first capacitor C1 is charged until the second switch is turned into “OFF” state; (3) At a third time point, the first switch is still “ON” state and the third switch is “OFF” state, and the second switch is initially turned into “ON” state after the potential on the data line is initially adjusted to be a written data potential; and (4) after a fourth time point, the first switch is turned into “OFF” state, and thereby the potential on the data line is terminated to be transferred to the first end of the first capacitor; the second switch and the third switch are both turned into “ON” state, the second predetermined potential is initially introduced into the interior of the driving circuit, and the potential on the data line is retrieved back to the precharged potential. Wherein said second time point is later than said first time point, said third time point is later than said second time point, and said fourth time point is later than said third time point.

In accordance with another embodiment of the present invention, there is provided another driving circuit adapted to drive a current-driven device that has a first terminal and a second terminal, wherein the first terminal of the current-driven device is electrically coupled to a first predetermined potential. The driving circuit includes a switch module, a first capacitor and a second capacitor. The switch module is electrically coupled to a data line, a second terminal of the current-driven device, and a second predetermined potential and further is for determining whether allowing a current to flow through the current-driven device; a first capacitor has a first end and a second end, and the first end and the second end of the first capacitor are respectively electrically coupled to different nodes in the switch module. The first end of the first capacitor is electrically coupled to receive a potential on the data line in a particular time period. A first end of the second capacitor is electrically coupled with the second end of the first capacitor, while a second end of the second capacitor is electrically coupled to the second predetermined potential.

In accordance with one embodiment of the present invention, the driving circuit is as mentioned above, wherein a capacitance of said second capacitor is larger than that of the first capacitor.

In accordance with yet another embodiment of the present invention, said switch module includes a plurality of switches, and each of the switches includes a control end, a first passage end and a second passage end. Specifically, the switch module includes a first switch, a second switch, and a third switch. The control end of the first switch is electrically coupled to a first control signal, and it is determined whether transferring a potential on the data line from the first passage end of the first switch to the second passage end of the first switch based on the first control signal. The control end of the second switch is electrically coupled to the second passage end of the first switch, the first passage end of the second switch is electrically coupled to the second terminal of the current-driven device. The control end of the third switch is electrically coupled to a second control signal, the first passage end of the third switch is electrically coupled to the second passage end of the second switch, and the second passage of the third switch electrically coupled to the second predetermined potential.

In accordance with one embodiment of the present invention, the two ends of said first capacitor are respectively coupled to the control end and the second passage end of the second switch; and the two ends of said second capacitor are respectively connected to the first passage end and the second passage end of the third switch.
In accordance with exemplary embodiments of the present invention, a new design and arrangement of structure of driving circuits including three switches such as transistors and two capacitors is utilized, and it results in a current flowing through OLED in a light emission stage that is unrelated to threshold voltages of transistors. Therefore, threshold voltage differences among different pixel circuits to cause driving current variations are avoided and the influence of fabrication process of transistors is excluded.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

Hereinafter, an exemplary embodiment of the present invention will be described in detail. However, the present invention is not limited to the embodiments disclosed below, but can be implemented in various types. Therefore, the present embodiment is provided for complete disclosure of the present invention and to fully inform scope of the present invention to those ordinary skilled in the art. These and other features and advantages of the various embodiments disclosed herein will be better understood with respect to the following description and drawings, in which like numbers refer to like parts throughout.

FIG. 1 illustrates a circuit diagram of a conventional pixel circuit for an OLED display device.

FIG. 2 illustrates a circuit diagram of a driving circuit for driving a current-driven device according to an exemplary embodiment of the present invention.

FIG. 3 illustrates a plurality of signal timing sequences in relation to the driving circuit as shown in FIG. 2.

FIG. 4(a) illustrates an simulation curve of effect about driving an OLED in use of a conventional driving circuit as shown in FIG. 1.

FIG. 4(b) illustrates an simulation curve of effect about driving an OLED in use of the driving circuit as shown in FIG. 2 when the capacitance of a capacitor C2 is larger than another capacitance of a capacitor C1

FIG. 4(c) illustrates a simulation curve of effect about driving an OLED in use of the driving circuit as shown in FIG. 2 when capacitances of capacitors C1 and C2 are equal.

FIG. 4(d) illustrates an simulation curve of effect about driving an OLED in use of the driving circuit as shown in FIG. 2 on the assumption of without a capacitor C2.

FIG. 5 illustrates a relationship of electrical connection between another driving circuit and an OLED.

FIG. 6 illustrates a relationship of electrical connection between yet another driving circuit and an OLED.

FIG. 7 illustrates a plurality of signal timing sequences in relation to the driving circuit as shown in FIG. 6.

### DETAILED DESCRIPTION

It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings.

Referring to FIG. 2, FIG. 2 illustrates a circuit diagram of a driving circuit for driving a current-driven device according to an exemplary embodiment of the present invention. As shown in FIG. 2, a relationship of electrical connection between the driving circuit and an OLED is illustrated, and the driving circuit 22 adapted to drive a current-driven device such as an OLED 26 is a three-transistor, two-capacitor structure (3T2C). The driving circuit 22 includes transistors M1, M2, and M3 and capacitors C1 and C2. In addition, transistors M1, M2, and M3 are all N-type transistors. In this embodiment, transistors M1, M2, and M3 are all used as switches, and the gate, source and drain for each of the transistors M1, M2, and M3 respectively serve as a control end, a first passage end and a second passage end of one the switch. Furthermore, transistors M1, M2, and M3 are constructed to be a switch module for determining whether to allow a current to flow through the OLED 26.

More specifically, the gate of the N-type transistor M1 is electrically coupled to a control signal S1 and determines whether transmitting the potential on a data line DL from the drain of the N-type transistor M1 to the source of the N-type transistor M1 based on the control signal S1. The drain of the N-type transistor M1 is electrically coupled to the data line DL. The gate of the N-type transistor M2 is electrically coupled to the source of the N-type transistor M1, and the drain of the N-type transistor M2 is electrically coupled to a cathode of the OLED 26. An anode of the OLED 26 is electrically coupled to a power source potential OVDD. The gate of the N-type transistor M3 is electrically coupled to a control signal S2, the drain of the N-type transistor M3 is electrically coupled to the source of the N-type transistor M2, and the source of the N-type transistor M3 is electrically coupled to another power source potential OVSS. A first end and a second end of the capacitor C1 are respectively electrically coupled to the gate and the source of the N-type transistor M2. A first end and a second end of the capacitor C2 are respectively electrically coupled to the drain and the source of the N-type transistor M3.

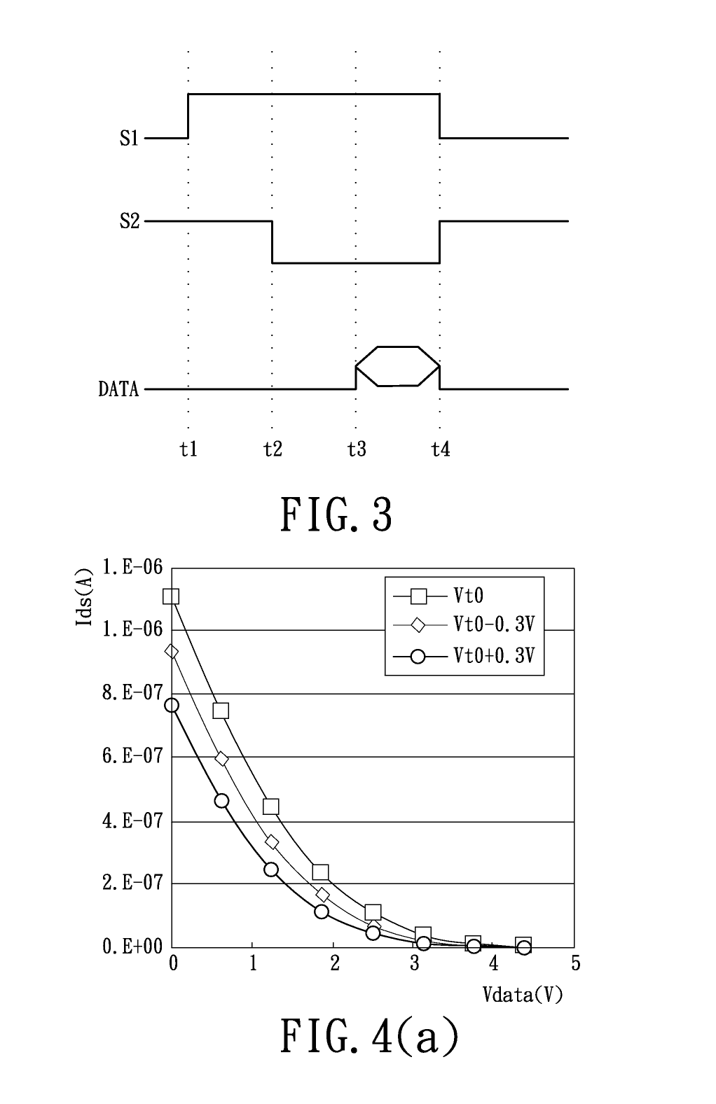

Turning to FIG. 3, there is shown a plurality of signal timing sequences in relation to the driving circuit 22 as shown in FIG. 2. Referring to FIG. 2 and FIG. 3 together, the specific operation of the driving circuit 22 will be described in details as follows.

More specifically, at a time point t1, the control signal 51 is turned into a logic “HIGH” level, and the control signal S2 is at a logic “HIGH” level. The data signal DATA on the data line DL is at a precharged potential (hereinafter, referred to as Vref), which is provided to the drain of the N-type transistor M1. At this moment, the N-type transistors M1, M2, and M3 are all “ON” state, and the precharged potential Vref on the data line DL is initially transferred/delivered to the first end of the capacitor C1. The gate potential of the N-type transistor M2 (hereinafter, referred to as Vg) is at Vref, and the source potential of the N-type transistor M2 (hereinafter, referred to as Vs) is OVSS.

At a time point t2, the control signal 51 is still at the logic “HIGH” level, and the control signal S2 is turned into a logic “LOW” level. The potential of the data signal DATA is still at the precharged potential Vref, which is provided to the drain of the N-type transistor M1 from the data line DL. At this moment, the N-type transistors M1, M2 both are “ON” states, and M3 is turned into “OFF” state, and the power source potential OVSS is terminated to be introduced into the drain of the N-type transistor M3 of the driving circuit 22. The gate potential Vg of the N-type transistor M2 is still at the Vref, and since the N-type transistor M2 is “ON” state, a ON-state current (i.e., generally conduction current) of the N-type transistor M2 charges the capacitor C2 until the source potential Vs of the N-type transistor M2 rises up to (Vref-Vth). After that, the N-type transistor M2 is turned into “OFF” state, the current is reduced to 0 and thus stopping charging the capacitor C2. The source potential Vs of the N-type transistor M2 is fixed/maintained at (Vref-Vth), where Vth represents the threshold voltage of the N-type transistor M2.

At a time point t3, the control signal S1 is still at the logic “HIGH” level, and control signal S2 is at the logic “LOW” level. The N-type transistors M1 is “ON” state, and the N-type transistor M3 is “OFF” state. After the precharged potential Vref on the data line DL is adjusted to be a written data potential (hereinafter, referred to as Vdata), the N-type transistors M2 starts to be turned into “ON” state. The gate potential Vg of the N-type transistor M2 is Vdata, and the source potential Vs of the N-type transistor M2 is turned into [(Vref-Vth)+a(Vdata-Vref)], where a=C1/C1+C2.

After a time point t4, the OLED 26 is at a light emission stage. The control signals S1 is turned into a logic “LOW” level, and S2 is turned into the logic “HIGH” level. The potential of the data signal DATA is changed from the written data potential Vdata back to the precharged potential. Vref. At this moment, the N-type transistors M1 is turned into “OFF” state, and the N-type transistors M2 and M3 are both turned into “ON” state, so that the potential on the data line DL is terminated to be transferred to the first end of the capacitor C1; the gate potential Vg of the N-type transistor M2 becomes [Vdata+OVSS-Vref+Vth-a(Vdata-Vref)], and the source potential Vs of the N-type transistor M2 is changed back to OVSS. At this moment, a current flowing through the OLED 26 is Ids=k(Vgs-Vth)²=k[(1-a)(Vdata-Vref)]², thus it is found that, the current flowing through the OLED 26 is unrelated to the threshold voltage Vth of the N-type transistor M2, so that the influence of fabrication process of transistors applied to the current flowing through the OLED 26 is excluded.

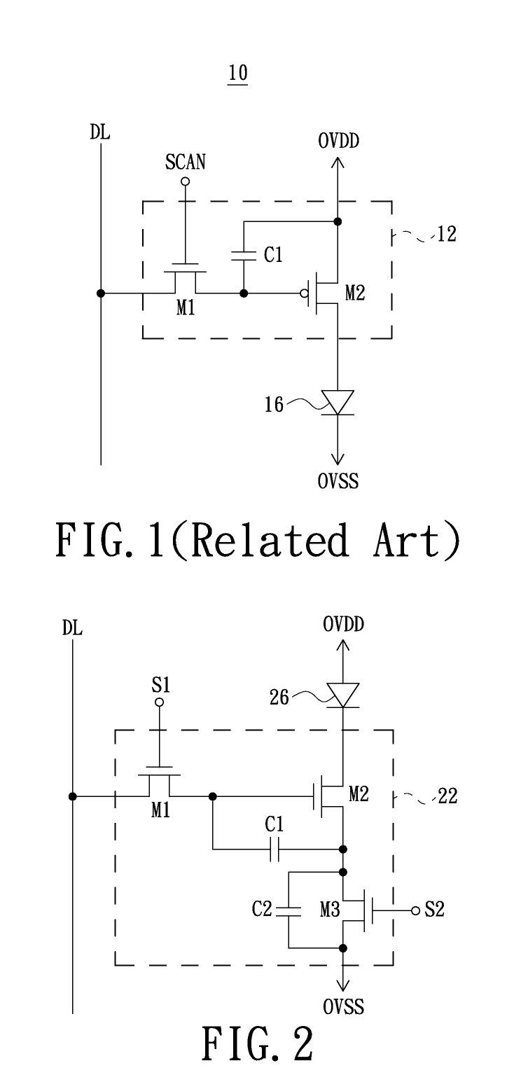

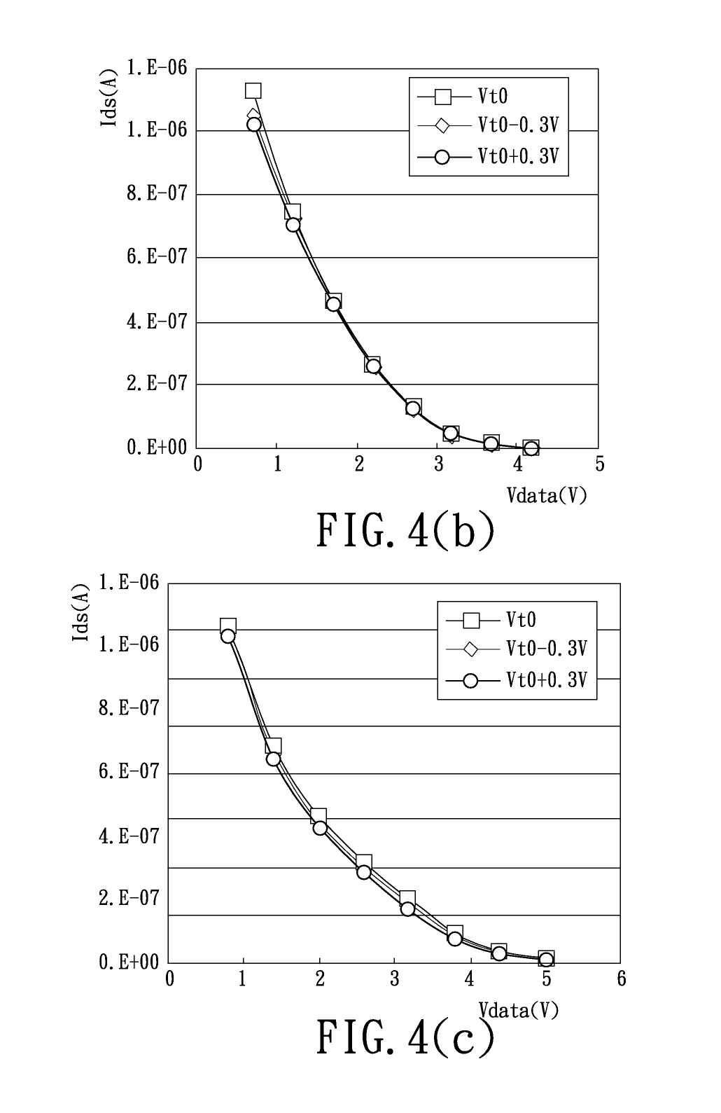

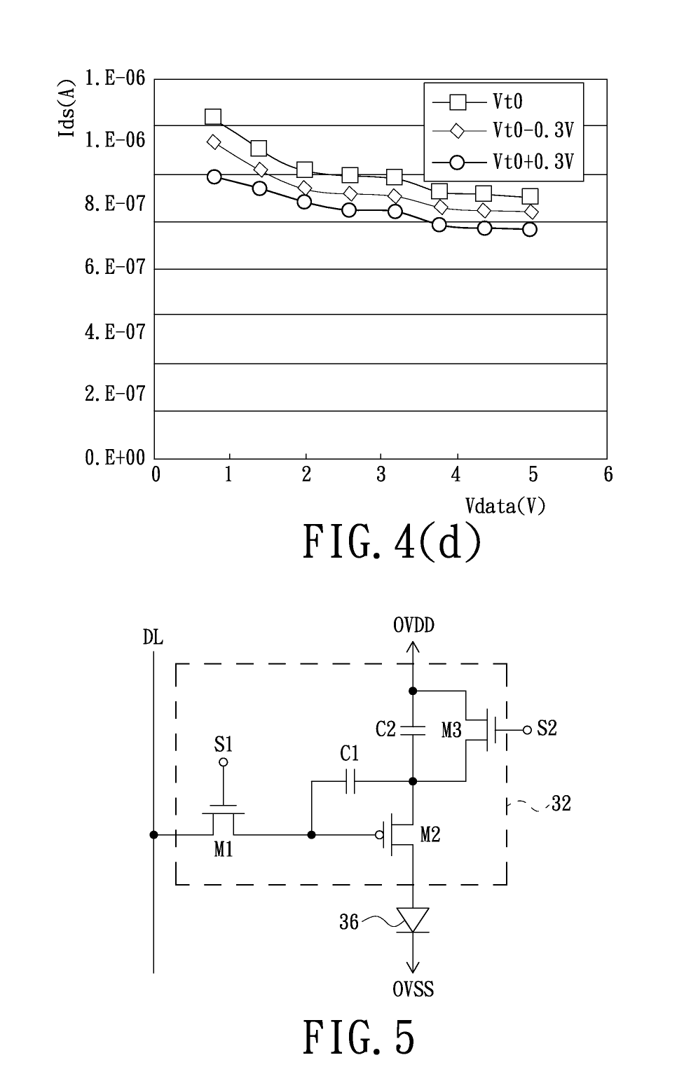

FIG. 4(a)-FIG. 4(d) show examples of simulation curves, represented by Ids vs. Vdata, to simulate effects about driving an OLED. In particular, FIG. 4(a) illustrates an simulation curve of effect about driving the OLED in use of the conventional driving circuit 12 (as shown in FIG. 1), FIG. 4(b) illustrates an simulation curve of effect about driving the OLED in use of the driving circuit 22 (as shown in FIG. 2) according to an exemplary embodiment of the present invention when the capacitance of the capacitor C2 is larger than the capacitance of the capacitor C1, FIG. 4(c) illustrates a simulation curve of effect about driving the OLED in use of the driving circuit 22 (as shown in FIG. 2) when the capacitances of the capacitors C1 and C2 are equal, and FIG. 4(d) illustrates an simulation curve of effect about driving the OLED in use of the driving circuit 22 as shown in FIG. 2 on the assumption of without the capacitor C2. In FIG. 4(a)-FIG. 4(d), the characteristic curves of Ids vs. Vdata are illustrated respectively under three situations that values of the threshold voltage Vth of the N-type transistor M2 as Vt0, negatively drifted to (Vt0-0.3) and positively drifted to (Vt0+0.3). In comparison of FIG. 4(a)-FIG. 4(d), a better driving effect than the prior art is obtained by adopting the driving circuit 22 according to an embodiment of the present invention. Speaking of adopting an embodiment of the present invention, there are two capacitors C1 and C2 configured in the driving circuit 22, a better driving effect is obtained when the capacitance of the capacitor C2 is larger than that of the capacitor C1. If there is no capacitor C2 and only the capacitor C1 configured in the driving circuit, it might cause a relatively worse effect that the current Ids flowing through the OLED varied along with the variation of Vdata is very slight.

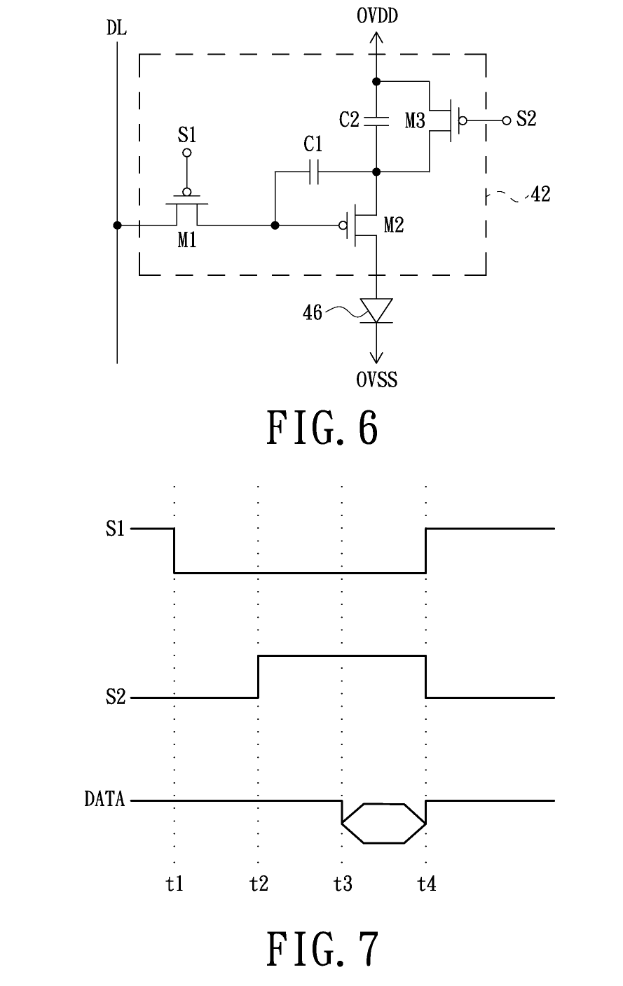

While the above description has been given, it is understood that this invention is not limited to the disclosed embodiment as shown in FIG. 2, various arrangements of the driving circuit can be used such as shown in FIG. 5 and FIG. 6. The detailed description will be given as follows.

The FIG. 5 illustrates a relationship of electrical connection between another driving circuit and an OLED. As shown in FIG. 5, a driving circuit 32 adapted to drive a current-driven device such as an OLED 36 is a three-transistor, two-capacitor structure (3T2C). The driving circuit 32 includes transistors M1, M2, and M3 and capacitors C1 and C2. In addition, transistors M1 and M3 are both N-type transistors, and transistor M2 is a P-type transistor. In this embodiment, transistors M1, M2, and M3 are all used as switches, and the gate, drain and source for each of the transistors M1, M2, and M3 are respectively represented as a control end, a first passage end and a second passage end of one the switch. Furthermore, transistors M1, M2, and M3 are constructed to be a switch module for determining whether to allow a current to flow through the OLED 36.

More specifically, the gate of the N-type transistor M1 is electrically coupled to a control signal S1 and determines whether transmitting a potential on a data line DL from the drain of the N-type transistor M1 to the source of the N-type transistor M1 based on the control signal S1. The drain of the N-type transistor M1 is electrically coupled to the data line DL. The gate of the P-type transistor M2 is electrically coupled to the source of the N-type transistor M1, and the drain of the P-type transistor M2 is electrically coupled to an anode of the OLED 36, and further an cathode of the OLED 36 is electrically coupled to a power source potential OVSS. The gate of the N-type transistor M3 is electrically coupled to a control signal S2, the drain of the N-type transistor M3 is electrically coupled to another power source potential OVDD, and the source of the N-type transistor M3 is electrically coupled to the source of the P-type transistor M2. A first end and a second end of the capacitor C1 are respectively electrically coupled to the gate and the source of the P-type transistor M2. A first end and a second end of the capacitor C2 are respectively electrically coupled to the drain and the source of the N-type transistor M3. The specific operation of the driving circuit 32 is similar to that of the driving circuit 22 as shown in FIG. 2, and therefore a detailed description herein is omitted.

Referring to FIG. 6, the FIG. 6 illustrates a relationship of another electrical connection between yet another driving circuit and an OLED. As shown in FIG. 6, a driving circuit 42 adapted to drive a current-driven device such as an OLED 46 is a three-transistor, two-capacitor structure (3T2C) structure. The driving circuit 42 includes transistors M1, M2, and M3 and capacitors C1 and C2. In addition, transistors M1, M2 and M3 are all P-type transistors. In this embodiment, M1, M2, and M3 are all used as switches, and the gate, drain and source for each of the transistors M1, M2, and M3 are respectively represented as a control end, a first passage end and a second passage end of one the switch. Furthermore, M1, M2, and M3 are constructed to be a switch module for determining whether to allow a current to flow through the OLED 46.

More specifically, the gate of the P-type transistor M1 is electrically coupled to a control signal 51 and determines whether transmitting the potential on a data line DL from the source of the P-type transistor M1 to the drain of the P-type transistor M1 based on the control signal S1. The source of the N-type transistor M1 is electrically coupled to the data line DL. The gate of the P-type transistor M2 is electrically coupled to the drain of the P-type transistor M1, and the drain of the P-type transistor M2 is electrically coupled to an anode of the OLED 46, and further an cathode of the OLED 46 is electrically coupled to a power source potential OVSS. The gate of the P-type transistor M3 is electrically coupled to a control signal S2, the drain of the P-type transistor M3 is electrically coupled to the source of the P-type transistor M2, and the source of the P-type transistor M3 is electrically coupled to another power source potential OVDD. A first end and a second end of the capacitor C1 are respectively electrically coupled to the gate and the source of the P-type transistor M2. A first end and a second end of the capacitor C2 are respectively electrically coupled to the drain and the source of the P-type transistor M3.

Turning to FIG. 7, there is shown a plurality of signal timing sequences in relation to the driving circuit 42 according to one embodiment of the present invention. By incorporating FIG. 6 and FIG. 7, a specific operation of the driving circuit 42 will be described in details as follows.

More specifically, at a time point t1, the control signal 51 is turned into a logic “LOW” level, and the control signal S2 is at a logic “LOW” level. The potential of the data signal DATA is at a precharged potential (hereinafter, referred to as Vref), which is provided to the source of the P-type transistor M1. At this moment, the P-type transistors M1, M2, and M3 are all “ON” state, and the precharged potential Vref on the data line DL is initially transferred to the first end of the capacitor C1. The gate potential of the P-type transistor M2 (hereinafter, referred to as Vg) is at Vref, and the source potential of the P-type transistor M2 (hereinafter, referred to as Vs) is OVDD.

At a time point t2, the control signals S1 is still at the logic “LOW” level, the control signal S2 turns into a logic “HIGH” level. The potential of the data signal DATA is still at the precharged potential Vref, which is provided to the source of the P-type transistor M1. At this moment, the P-type transistors M1, M2 are both “ON” states, and M3 is “OFF” state. The power source voltage OVDD is terminated to be introduced into the drain of the P-type transistor M3 of the driving circuit 42. The gate potential Vg of the N-type transistor M2 is still at Vref, and since the P-type transistors M2 is “ON” state, the ON-state current of the P-type transistor M2 charges the capacitor C2 until the source potential Vs of the P-type transistor M2 rises up to (Vref+Vth). After that, the P-type transistors M2 is turned into “OFF” state, and the current is reduced to be equal to 0 so that stopping charging the capacitor C2. The source potential Vs of the P-type transistor M2 is fixed at (Vref+Vth), where Vth represents the threshold voltage of the P-type transistor M2.

At a time point t3, the control signal S1 is still at the logic “LOW” level, and the control signal S2 is at the logic “HIGH” level. The P-type transistors M1 is “ON” state, and the P-type transistor M3 is “OFF” state. After the precharged potential Vref on the data line DL is adjusted to be a written data potential (hereinafter, referred to as Vdata), the P-type transistors M2 is turned into “ON” state. The gate potential Vg of the P-type transistor M2 is Vdata, and the source potential Vs of the P-type transistor M2 is turned into [(Vref +Vth)+a(Vdata-Vref)], where a=C1/C1+C2.

After a time point t4, the OLED 46 is at a light emission stage. The control signals S1 is turned into a logic “HIGH” level, and the control signal S2 is turned into the logic “LOW” level. The potential of the data signal DATA is changed from the written data potential Vdata back to the precharged potential Vref. At this moment, the P-type transistor M1 is turned into “OFF” state, and the P-type transistors M2 and M3 are both “ON” state, so that the potential on data line DL is terminated to be transferred to the first end of the capacitor C1; the gate potential Vg of the N-type transistor M2 becomes [Vdata+OVDD-Vref-Vth-a(Vdata-Vref)], and the source potential Vs of the P-type transistor M2 becomes OVDD. At this moment, a current flowing through the OLED 46 is Ids=k(Vsg-Vth)²=k[(1-a)(Vref-Vdata)]², thus it is found that, the current flowing through the OLED 46 is unrelated to the threshold voltage Vth of the P-type transistor M2, so that the influence of fabrication process of transistors applied to the current flowing through the OLED 46 is excluded.

While the invention has been described in terms of exemplary embodiments, those skilled in the art will recognize that the invention can be practiced with modifications and in the spirit and scope of the appended claims.

In conclusion, the driving circuit as described above utilizes a new design and arrangement of structure, including three switches such as transistors and two capacitors, according to exemplary embodiments of the present invention. Consequently, the current flowing through the current-driven device such as OLED is unrelated to threshold voltages of transistors implemented in the driving circuit, and thereby the issues of driving current variations caused by threshold voltage differences associated with the prior art are avoided by leaving out the influence of fabrication process of transistors applied to the current flowing through the OLED.

Furthermore, given the above disclosure, one skilled in the art could devise variations, for example, suitably changing the type of the transistors (P-type or N-type), interchanging electrical connections of the source and the drain of each of the implemented transistors, and the like.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A driving circuit adapted to drive a current-driven device that has a first terminal and a second terminal, the first terminal being electrically coupled to a first predetermined potential, the driving circuit having a plurality of switches, and each of the switches having a control end, a first passage end and a second passage end; the driving circuit comprising:
a first switch, wherein the control end of the first switch is electrically coupled to a first control signal, the first switch is for determining whether allowing a potential on a data line to be transferred from the first passage end of the first switch to the second passage end of the first switch based on the first control signal;
a second switch, wherein the control end of the second switch is electrically coupled to the second passage end of the first switch, the first passage end of the second switch is electrically coupled to the second terminal of the current-driven device;
a third switch, wherein the control end of the third switch is electrically coupled to a second control signal, the first passage end of the third switch is electrically coupled to the second passage end of the second switch, and the second passage end of the third switch is electrically coupled to a second predetermined potential;
a first capacitor, wherein two ends of the first capacitor are respectively electrically coupled to the control end of the second switch and the second passage end of the second switch; and
a second capacitor, wherein two ends of the second capacitor are respectively electrically coupled to the first passage end of the third switch and the second passage end of the third switch.

2. The driving circuit as claimed in claim 1, wherein a capacitance of the second capacitor is larger than that of the first capacitor.

3. The driving circuit as claimed in claim 1, wherein the first switch, the second switch and the third switch are all N-type transistors.

4. The driving circuit as claimed in claim 1, wherein the first switch and the third switch are both N-type transistors, and the second switch is a P-type transistor.

5. The driving circuit as claimed in claim 1, wherein the first switch, the second switch and the third switch are all P-type transistors.

6. A method of driving an current-driven device applicable to the driving circuit as claimed in claim 1, comprising steps of:
transferring a precharged potential on the data line to the second passage end of the first switch when all the first through third switches in the driving circuit are all “ON” states, and thereby the first capacitor is charged by the precharged potential;
disabling the second predetermined potential to be introduced into the driving circuit when the third switch is OFF state;
adjusting the potential on the data line to be a written data potential when the second switch is OFF state due to the potential on the end of the second capacitor electrically coupled to the second passage end of the second switch is charged to reach a level for switching off the second switch; and
recovering the potential on the data line from the written data potential back to the precharged potential when the first switch is OFF state.

7. A driving circuit adapted to drive a current-driven device that has a first terminal and a second terminal, the first terminal being electrically coupled to a first predetermined potential;
the driving circuit comprising:
a switch module, being electrically coupled to a data line, the second terminal of the current-driven device, and a second predetermined potential and being for determining whether allowing a current to flow through the current-driven device;
a first capacitor, having a first end and a second end, wherein the first end and the second end of the first capacitor are respectively electrically coupled to different nodes in the switch module, and the first end of the first capacitor is electrically coupled to receive a potential on the data line in a particular time period; and
a second capacitor, having a first end and a second end, wherein the first end of the second capacitor is electrically coupled to the second end of the first capacitor, and the second end of the second capacitor is electrically coupled to the second predetermined potential.

8. The driving circuit as claimed in claim 7, wherein a capacitance of the second capacitor is larger than that of the first capacitor.

9. The driving circuit as claimed in claim 7, wherein the switch module comprises a plurality of switches and each of the switches has a control end, a first passage end and a second passage end, the switches comprising:
a first switch, wherein the control end of the first switch is electrically coupled to a first control signal, and the first switch is for determining whether allowing the potential on the data line to be transferred from the first passage end of the first switch to the second passage end of the first switch based on the first control signal;
a second switch, wherein the control end of the second switch is electrically coupled to the second passage end of the first switch, and the first passage end of the second switch is electrically coupled to the second terminal of the current-driven device; and
a third switch, wherein the control end of the third switch is electrically coupled to a second control signal, the first passage end of the third switch is electrically coupled to the second passage end of the second switch, and the second passage end of the third switch is electrically coupled to the second predetermined potential.

10. The driving circuit as claimed in claim 9, wherein the first and the second ends of the first capacitor are respectively electrically coupled to the control end of the second switch and the second passage end of the second switch, the first and the second ends of the second capacitor are respectively electrically coupled to the first passage end of the third switch and the second passage of the third switch.
